(19) United States
(12) Patent Application Publication
(10) Pub. No.: US 2015/0325767 A1
(43) Pub. Date: Nov. 12, 2015

(54) THERMOELECTRIC GENERATOR

(71) Applicant: Mahle International GmbH, Stuttgart (DE)

(72) Inventor: Thomas Himmer, Reichenbach (DE)

(21) Appl. No.: 14/704,271

(22) Filed: May 5, 2015

(30) Foreign Application Priority Data
May 6, 2014 (DE) 202014105519.3
Sep. 3, 2014 (DE) 102014219853.4

(51) Int. Cl. H01L 35/32; H01L 35/30

(52) U.S. Cl. CPC H01L 35/32; H01L 35/30

(57) ABSTRACT

The invention relates to a thermoelectric generator (1),
with a housing (2), which extends along a centre longitudinal axis (M) and delimits a housing interior (3).
with a supporting structure (4) provided in the housing interior (3) and extending along the centre longitudinal axis (M), which supporting structure divides the housing interior (3) into a radially outer fluid duct (5a) for flowing through by a first fluid (F₁) and with a radially inner fluid duct (5b), fluidically separated therefrom, for flowing through by a second fluid (F₂),
wherein the supporting structure (4) in a cross-section perpendicularly to the centre longitudinal axis (M) has the geometry of a polygon (SYMMETRY IN CIRCUMFERENTIAL DIRECTION?) with at least four corners (7), so that a supporting wall (6) of the supporting structure (4) is formed respectively between two adjacent corners (8) in cross-section,
wherein on each supporting wall (6) respectively at least one thermoelectric module (8) is arranged, which is able to be thermally connected with the two fluids (F₁, F₂).

The invention relates to a thermoelectric generator.

The term “thermoelectricity” is understood to mean the reciprocal influencing of temperature and electricity and their conversion into one another. Thermoelectric materials utilize this influence in order to generate electrical energy as thermoelectric generators from waste heat, but are also used in the form of so-called heat pumps if, with the expenditure of electrical energy, heat is to be transported from a temperature reservoir with lower temperature into one with higher temperature.

The said thermoelectric generators are in fact used in automotive engineering in the cooling of the most varied of components such as e.g. modern lithium-ion batteries, which develop waste heat to a considerable extent under normal operating conditions. Thermoelectric generators can, however, also be used in electric motor vehicles as a combined heating and cooling device, for instance for controlling the temperature of the passenger compartment, especially since they have a distinctly higher efficiency than for instance conventional electric resistance heaters; in motor vehicles with an internal combustion engine, the waste heat generated in the exhaust gas during the combustion process can be partially converted into electrical energy and fed into the on-board electrical system of the motor vehicle. The waste heat, converted into electrical energy, can therefore be utilized to a considerable proportion in order to reduce the energy consumption of the motor vehicle to a necessary minimum and hence to prevent an unnecessary emission of exhaust gases, such as CO₂ for instance. It is of crucial importance here to achieve as high an efficiency as possible, in order to convert heat into electrical energy or vice versa as effectively as possible.

It proves to be a problem in thermoelectric generators designed for use in motor vehicles that the installation space available in these is in most cases limited. In this respect, the need exists to provide thermoelectric generators which can also be installed in motor vehicles in which installation space is available only to a very limited extent, without this involving a loss of efficiency of the thermoelectric generators.

It is therefore an object of the present invention to provide an improved embodiment for a thermoelectric generator, which is distinguished in particular by a small installation space requirement.

This problem is solved by the subject of the independent claims. Preferred embodiments are the subject of the dependent claims.

A thermoelectric generator according to the invention comprises in a first aspect a housing delimiting a housing interior, which housing extends along a shared centre longitudinal axis. In the interior of the housing a supporting structure is provided, which serves for the mounting or respectively receiving of thermoelectric modules. The supporting structure also extends, like the housing, along said centre longitudinal axis. The supporting structure is, in addition, constructed such that it divides the housing interior into a radially outer fluid duct for flowing through by a first fluid and with a radially inner fluid duct, separated fluidically therefrom for flowing through by a second fluid.

The geometric shape of the supporting structure in a cross-section perpendicularly to the centre longitudinal axis is essential to the invention. In this cross-section, the supporting structure according to the invention has the shape of a polygon with at least four corners. Between two adjacent corners of the polygon in cross-section a supporting wall of the inner housing is formed here, so that all the supporting walls together produce the supporting structure. According to the invention, at least one thermoelectric module, able to be thermally connected with the two fluids, is provided on each supporting wall.

The geometric configuration of the supporting structure according to the invention in cross-section in the form of a polygon enables the provision of a large number of thermoelectric modules on a relatively small installation space. In this way, thermoelectric generators with a small installation space requirement and with nevertheless high efficiency can be realized.

For example, a supporting structure which has eight corners in cross-section, i.e. forms an octagon, has eight supporting walls, so that the thermoelectric generator according to the invention can comprise at least eight thermoelectric modules, which are arranged in a compact construction in a tight space.

Preferably, all the supporting walls are shaped integrally against each other to form the supporting structure.

In a preferred embodiment, in addition a bypass duct can be realized in the interior of the housing. In this case, the thermoelectric generator comprises an additional, inner housing, which is arranged in the housing interior within the supporting structure. The additional inner housing separates the radially inner fluid duct into a radially outer duct section for flowing through by the second fluid, and a radially inner duct section, fluidically separated therefrom, which can serve as a bypass duct for the first and/or the second fluid. The fluid flowing through the bypass duct does not enter into thermal operative connection with the thermoelectric modules.

In order to further reduce the installation space required for the entire thermoelectric generator, it is proposed in a preferred embodiment to provide in each supporting wall an aperture respectively for each thermoelectric module arranged on it, in which aperture the thermoelectric module is at least partially received, so that the thermoelectric module closes the aperture.

In an advantageous further development of this embodiment, the thermoelectric module is arranged in the aperture such that, in particular by means of a cover plate of the thermoelectric module constructed in a complementary manner to the aperture, it terminates flush with a radially outer exterior side of the supporting wall and projects radially inward into the radially inner fluid duct. Depending on whether the first fluid has a higher or lower temperature than the second fluid—flowing through the outer fluid duct—, a hot or cold side of the thermoelectric modules projects radially inward into the inner fluid duct. In this way, a particularly good thermal contact of the thermoelectrically active elements of the thermoelectric module with the first fluid flowing through the inner fluid duct can be achieved.

The installation space required by the entire thermoelectric generator can be further reduced by the housing and/or the additional, inner housing being equipped respectively with a substantially cylindrical geometry.

In order to keep the lost heat, which can not be used for generating electrical energy, as low as possible between adjacent thermoelectric modules, it is proposed in another preferred embodiment to provide a thermal insulation element of a thermally insulating material between two adjacent thermoelectric modules in cross-section. These can preferably be silicon dioxide-based or silicate-based shaped parts here. By means of such insulation elements, the thermal insulation between the two fluid ducts can be significantly improved.

In an advantageous further development of the invention, the thermal insulation elements rest respectively radially internally on the radially inner housing and radially externally on the supporting structure. In this way, the mechanical stability of the supporting structure in the housing interior can be considerably improved.

In another preferred embodiment, a rib-like structure is arranged on a radially inner internal side of the thermoelectric modules, which rib-like structure projects into the radially inner fluid duct. Such a rib-like structure serves to improve the thermal effective area of the thermoelectric modules with the second fluid flowing through the inner fluid duct. This measure brings about an improved efficiency of the thermoelectric generator.

In order to keep the own weight of the rib-like structure low with, at the same time, as large an effective area as possible, it is proposed to provide the rib-like structure with a wave-shaped geometry in cross-section. In order to ensure a good thermal contact with the thermoelectric module, it is recommended to fasten this radially externally in a materially connected manner, in particular by means of a soldered connection, on the radially inner internal side of the thermoelectric module. When the thermoelectric generator comprises an additional, inner housing, the rib-like structure is preferably to be constructed such that the ribs of the rib-like structure in cross-section rest radially internally on the additional, inner housing. In this way, the mechanical stability of the entire thermoelectric generator can be further improved.

In a further preferred embodiment, the supporting structure can rest on the outer housing by means of a plurality of holding webs extending respectively in radial direction. For this, said holding webs can be arranged along a circumferential direction of the housing at a distance from one another in the radially outer fluid duct.

In a second aspect, the thermoelectric generator according to the invention comprises an outer housing delimiting a housing interior. In the housing interior, an inner housing is arranged, which divides the housing interior into an outer fluid duct for flowing through by a first fluid and into an inner fluid duct, fluidically separated therefrom, for flowing through by a second fluid. The inner housing comprises a first and a second housing wall which lie opposite one another and in which respectively at least one aperture is provided. A thermoelectric module is inserted into each aperture, such that it closes the aperture. The thermoelectric generator according to the second aspect is distinguished by an extremely small installation space requirement and then lends itself in particular to use in a motor vehicle, when the bypass channel explained above in connection with the thermoelectric generator according to the first aspect can be dispensed with. According to the second aspect, the thermoelectric generator can be constructed in a particularly space-saving flat construction and can be realized for instance in the form of a flat tube.

If the thermoelectric generator is to be realized in a flat construction, which proves to be advantageous in particular in use in a motor vehicle, it is proposed to insert the thermoelectric module into the aperture such that it terminates flush with an exterior side of the housing facing the outer housing. For this, the thermoelectric module can comprise a cover plate, which then terminates flush with said exterior side of the housing. At the same time, however, it should also project inwards into the inner fluid duct. In this case, the two thermoelectric modules lie opposite one another in the inner fluid duct.

A particularly small space requirement for the thermoelectric generator can be achieved when the inner and/or the outer housing are constructed as a flat tube, which extends respectively along a main flow direction of the fluid flowing through the two fluid ducts.

In another preferred embodiment, the inner housing has a third and a fourth housing wall, which in a cross-section perpendicularly to the main flow direction complete the first and second housing wall to the inner housing. To improve efficiency of the thermoelectric generator, in said cross-section perpendicularly to the main flow direction a first thermally insulating insulation element is provided on an inner side of the third housing wall and a second thermally insulating insulation element is provided on an inner side of the fourth housing wall.

A particularly high thermal insulation effect can be achieved, however, by a first intermediate space, formed in cross-section perpendicularly to the main flow direction between the two thermoelectric modules and the third housing wall, being filled, in particularly completely, by the first thermally insulating insulation element. In an analogous manner thereto, a second intermediate space, formed in cross-section perpendicularly to the main flow direction between the two thermoelectric modules and the fourth housing wall, is filled, in particularly completely, by the second thermally insulating insulation element.

In an advantageous further development of the invention, which involves a particularly good thermal insulation of the two fluid ducts, the two thermally insulating insulation elements are part of a thermally insulating insulation device. This thermal insulation arrangement has, in a longitudinal section of the inner housing along the main flow direction, a U-shaped geometry with a base section and two legs projecting laterally from the base section. Here, the first thermally insulating insulation element forms a first leg and the second thermally insulating insulation element forms a second leg of the insulation device.

Particularly expediently, an aperture can be provided for flowing through by the second fluid.

A particularly preferred embodiment is associated with particularly low manufacturing costs, in which the thermally insulating insulation device is constructed as a structural part in which the two legs are formed integrally on the base section. Such a structural or shaped part can be produced from a silicate-based or silicon dioxide-based material.

Further important features and advantages of the invention will emerge from the subclaims, from the drawings and from the associated figure description with the aid of the drawings.

It shall be understood that the features mentioned above and to be explained in further detail below are able to be used not only in the respectively indicated combination, but also in other combinations or in isolation, without departing from the scope of the present invention.

Preferred example embodiments of the invention are illustrated in the drawings and are explained in further detail in the following description, wherein the same reference numbers refer to identical or similar or functionally identical components.

There are shown, respectively diagrammatically

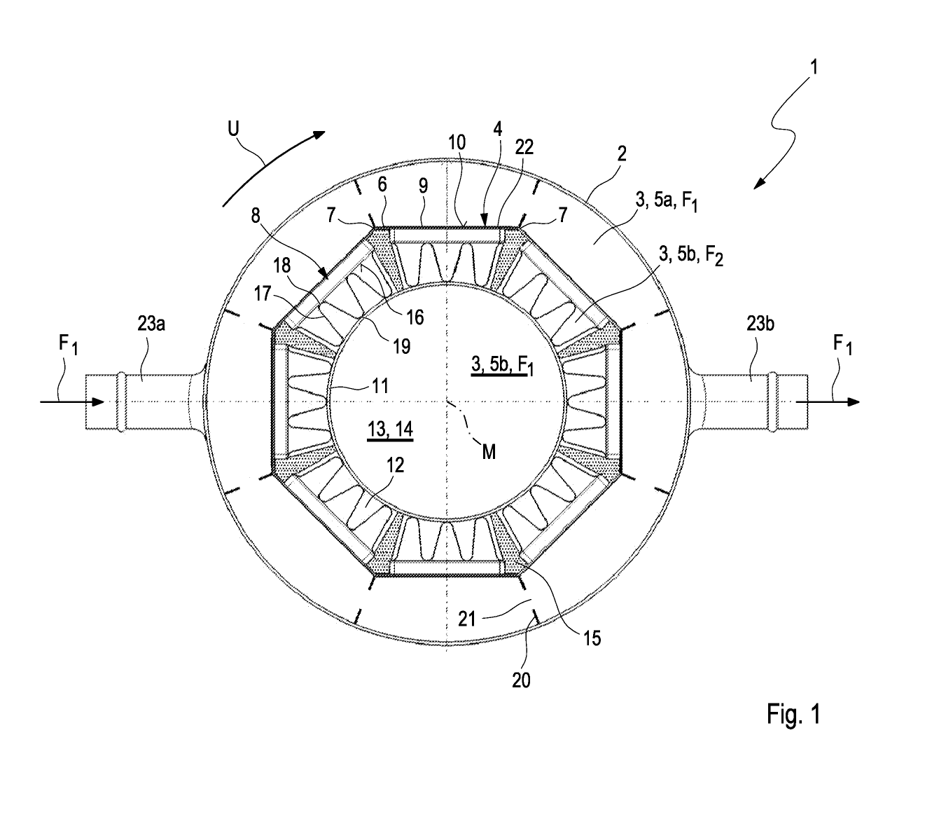

FIG. 1 a first example of a thermoelectric generator according to the invention in a cross-section perpendicularly to a centre longitudinal axis of the housing of the generator,

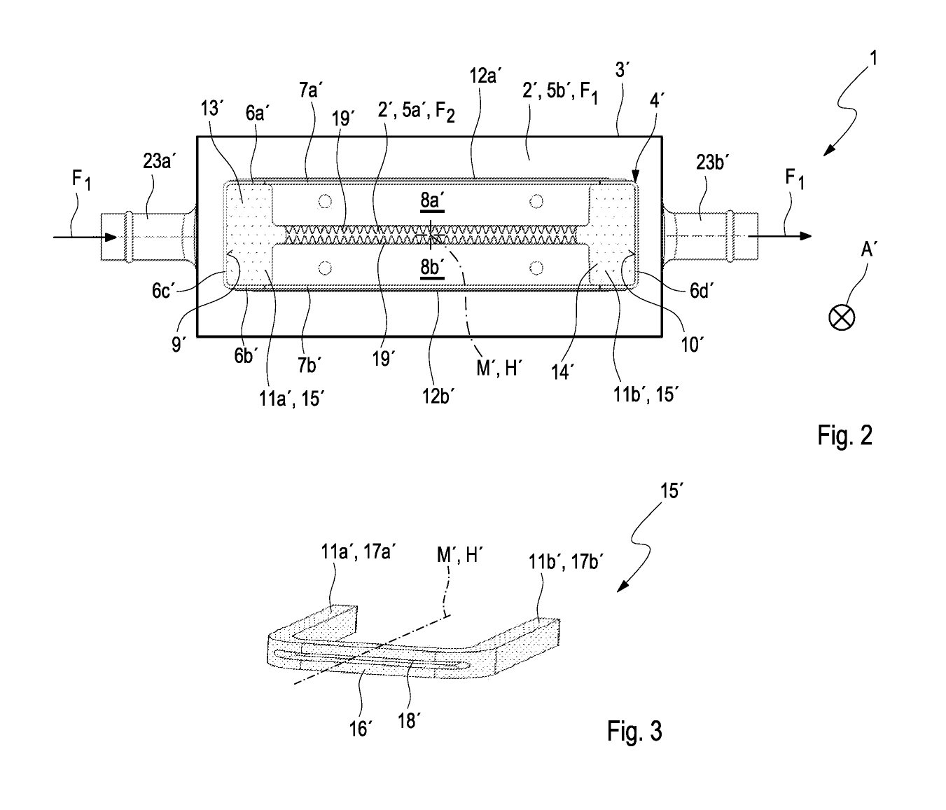

FIG. 2 a second example of a thermoelectric generator according to the invention in a cross-section perpendicularly to a centre longitudinal axis of the housing of the generator,

FIG. 3 a detail illustration of a thermoelectric insulation device in an isometric view.

FIG. 1 shows in a cross-section an example of a thermoelectric generator 1 according to the invention in accordance with the first aspect. The thermoelectric generator 1 comprises a sufficiently dimensioned housing 2, which delimits a housing interior 3. The housing 2 extends along a centre longitudinal axis M. FIG. 1 shows the thermoelectric generator in a cross-section perpendicularly to this centre longitudinal axis M. In the housing interior 3 a supporting structure 4 is provided for supporting or respectively receiving thermoelectric modules, which also extends along the centre longitudinal axis M and divides the housing interior 3 into a radially outer fluid duct 5a with respect to the centre longitudinal axis M for flowing through by a first fluid F₁ and with a radially inner fluid duct 5b, fluidically separated therefrom, for flowing through by a second fluid F₂. The first fluid F₁ can enter via a fluid inlet 23a into the radially outer fluid duct 5b and exit again from the fluid duct 5a via a fluid outlet 23b. For the second fluid F₂ a corresponding fluid inlet or respectively fluid outlet can be provided on the face side on the housing 2 (not shown in FIG. 1).

In cross-section perpendicularly to the centre longitudinal axis M, the supporting structure 4 has the geometry of a polygon. In the example of FIG. 1, the polygon is an octagon, i.e. it has eight corners 7. In variants, however, the polygon can also have a different number of corners, for example four or six corners. Two adjacent corners 7 in cross-section respectively form here a respective supporting wall 6 of the supporting structure 4. As FIG. 1 clearly demonstrates, the polygon can be constructed in the form of a regular polygon with respectively identical supporting walls 6. In the regular octagon of FIG. 1, therefore, the distance, defined by the supporting wall 6, between two adjacent corners 7 is identical for all supporting walls 6. On each supporting wall 6 respectively at least one thermoelectric module 8 is arranged, which is able to be thermally connected with the two fluids. The thermoelectric modules 8 comprise, in a known manner, thermoelectric elements of a thermoelectrically active material such as, for example, bismuth telluride or Half-Heusler materials.

For the arrangement of the thermoelectric modules 8 on the supporting structure 4, at least one aperture 9 can be provided respectively in each supporting wall 6 for each thermoelectric module 8, in which aperture a thermoelectric module 8 is at least partially received. In order to ensure the fluidic separation of the two fluid ducts 5a, 5b, the thermoelectric modules 8 and the apertures 9 are dimensioned such that a respective thermoelectric module 8 closes the aperture 9 associated with it. Preferably, the thermoelectric modules 8 are arranged in the apertures 9 such that they terminate by means of a cover plate 22 flush with a respective radially outer exterior side 10 of the supporting wall 6 and project radially inwards into the radially inner fluid duct 5a. Depending on whether the first fluid F₁ has a higher or lower temperature than the second fluid F₂, therefore either the hot side or the cold side of the thermoelectric modules 8 projects radially inwards into the inner fluid duct 5b. This measure brings about a particularly good thermal contact of the thermoelectric modules 8 with the second fluid F₂ flowing through the inner fluid duct 5b.

It can also be seen from FIG. 1 that the thermoelectric generator 1 comprises an additional inner housing 11, which is arranged in cross-section perpendicularly to the centre longitudinal axis M in the housing interior 3 radially within the supporting structure 4. Preferably the housing 2 and—if present—the additional inner housing 11, as illustrated in FIG. 1, can be respectively equipped with a substantially cylindrical geometry. The additional, inner housing 11 separates the radially inner fluid duct 5b into a radially outer duct section 12 for flowing through by the second fluid F₂ and a radially inner duct section 13, fluidically separated therefrom, which serves as a bypass duct 14 for the first fluid F₁ and alternatively or additionally for the second fluid F₂. The fluid flowing through the bypass duct 14 is directed past the thermoelectric modules 8 and can therefore not enter into interaction with the second fluid F₂.

In order to keep the lost heat between adjacent thermoelectric modules 8 low, in accordance with FIG. 1 a thermally insulating thermal insulation element 15 in the form of a silicon dioxide-based or silicate-based structural or shaped part is provided between two adjacent thermoelectric modules 8 in cross-section in circumferential direction U. All materials, the thermal conductivity of which, compared with the thermal conductivity of the materials used for the thermoelectric modules 8 has only a fraction of the values thereof are understood as being “thermally insulating” in the context of the present invention.

For the stable fastening of the thermal insulation elements 15 in the housing interior 3, these rest respectively radially internally on the additional, inner housing 11 and radially externally on the supporting structure 4. In this way, the mechanical stability of the supporting structure 4 in the housing interior 3 is also improved.

As FIG. 1 additionally shows, a rib-like structure 17 is arranged on a radially inner internal side 16 of the thermoelectric modules 8, which rib-like structure projects into the radially inner fluid duct 5b. The rib-like structure serves for enlarging the thermal effective area of the thermoelectric modules 8 with the second fluid F₂ flowing through the inner fluid duct 5b. In the cross-section shown in FIG. 1, the rib-like structure 17 has a wave-shaped geometry. The rib-like structure 17 is fastened with end sections 18, proximal to the respective thermoelectric module 8, in a materially connected manner, for example by means of a soldered connection, on the radially inner internal side of the thermoelectric module 8. This brings about a particularly good thermal contact of the rib-like structure 17 with the respective thermoelectric module 8.

When the thermoelectric generator 1, as shown in FIG. 1, has an additional, inner housing 11, the ribs of the rib-like structure 17 in cross-section perpendicularly to the centre longitudinal axis M preferably rest with their distal end section 19, with respect to the thermoelectric module 8, i.e. radially internally, on the inner housing 11.

Irrespective thereof, the thermoelectric generator 1 can comprise a plurality of holding webs 20 extending in radial direction, by means of which the supporting structure 4 is able to rest on the housing 2. In each of the holding webs 20, an aperture 21 can be provided, in order to fluidically connect with one another the duct segments of the outer fluid duct 5b which are formed between adjacent holding webs 20. The holding webs 20 are arranged in cross-section perpendicularly to the centre longitudinal axis M preferably along the circumferential direction U of the housing 2 or respectively of the additional housing 11, at a distance from one another in the radially outer fluid duct 5a.

FIG. 2 shows an example of a thermoelectric generator 1′ according to the invention, in accordance with the second aspect, in a cross-section. The thermoelectric generator 1′ comprises an outer housing 3′, which extends along a centre longitudinal axis M′ and delimits a housing interior 2′. In the housing interior 2′ an inner housing 4′ is arranged, which divides the housing interior 2′ into an outer fluid duct 5a′ for flowing through by a first fluid F₁, and an inner fluid duct 5a′, fluidically separated therefrom, for flowing through by a second fluid F₂.

The first fluid F₁ can enter via a fluid inlet 23a′ into the radially outer fluid duct 5b and exit again from the fluid duct 5b′ via a fluid outlet 23b′. A corresponding fluid inlet or respectively fluid outlet can be provided on the face side on the housings 3′, 4′ (not shown in FIG. 2) for the second fluid F₂. The two housings 3′, 4′ are respectively constructed as a flat tube, which extend along a main flow direction H′ of the fluids F₁, F₂ flowing through the two fluid ducts 5a′, 5b′, corresponding to the centre longitudinal axis M′. FIG. 2 shows the two housings 3′, 4′ therefore in a cross-section perpendicularly to the centre longitudinal axis M′.

As illustrated in FIG. 2, the inner housing 4′ comprises a first and a second housing wall 6a′, 6b′, which lie opposite one another and in which respectively an aperture 7a′, 7b′ is provided. In variants of the example, also at least two such apertures 7a′, 7b′ can be provided in each housing wall 6a′, 6b′, which apertures can preferably be arranged adjacent to one another along an axial direction A′ defined by the centre longitudinal axis M′ (not shown). A thermoelectric module 8a′, 8b′ with thermoelectric elements, known to the specialist in the art, of a thermoelectrically active material, is inserted into each aperture 7a′, 7b′. The thermoelectric modules 8a′, 8b′ close the apertures 7a′, 7b′ in a fluid-tight manner. The two housing walls 6a′, 6b′ are completed in cross-section perpendicularly to the main flow direction H′ or respectively to the centre longitudinal axis M′ by a third and a fourth housing wall 6c′, 6d′ to the inner housing 4′. Two or more of the four housing walls 6a′-6d′ can be formed integrally against one another.

In accordance with FIG. 2, the thermoelectric modules 8a′, 8b′ are inserted into the apertures 7a′, 7b′ such that they respectively terminate by means of a cover plate 12a′, 12b′ flush with an exterior side of the inner housing 4′ facing the outer housing 3′ and project inwards into the inner fluid duct 5′a. Consequently, the two thermoelectric modules 8a′, 8b′ lie opposite one another in the inner fluid duct 5a′.

In the cross-section shown in FIG. 2, perpendicularly to the main flow direction H′ or respectively to the centre longitudinal axis M′ a first thermally insulating insulation element 11a′ is provided on an inner side 9′ of the third housing wall 6c′ and a second thermally insulating insulation element 11b′ is provided on an inner side 10′ of the fourth housing wall 6d′. The first insulation element 11a′ substantially completely fills a first intermediate space 13′ in cross-section perpendicularly to the main flow direction H′ or respectively to the centre longitudinal axis M′ partially delimited by the two thermoelectric modules 8a′, 8b′ and the third housing wall 6c′. Accordingly, the second insulation element 11b′ substantially completely fills a second intermediate space 14′ in cross-section partially delimited by the two thermoelectric modules 8a′, 8b′ and the fourth housing wall 6d′.

According to the illustration of FIG. 3, the thermal insulation elements 11a′, 11b can both be part of a thermally insulating insulation device 15′, which in a longitudinal section of the inner housing 4′ along the main flow direction H′ or respectively the centre longitudinal axis M′ has a U-shaped geometry with a base section 16′ and two legs 17a′, 17b′ projecting laterally from the base section 16′. For clarification, FIG. 3 shows the thermally insulating insulation device 15′ in an isometric view. It can be seen that the first thermally insulating insulation element 11a forms a first leg 17a′ and the second thermally insulating insulation element 11b′ forms a second leg of the U-shaped insulation device. The thermally insulating insulation device 15′ can be constructed as a structural or shaped part, in which the two legs 17a′, 17b′ are formed integrally on the base section 16′. In the base section 16′ an aperture 18′ can be provided, so that the latter can be flowed through by fluid. Silicon dioxide or a silicate come into consideration as material. The U-shaped thermal insulation device 15′ can be inserted into the inner housing 4′ such that it delimits the latter in said longitudinal section on three sides.

The thermoelectric modules 8a′, 8b′ of the thermoelectric generator 1′ can also have rib-like structures 19′, which lie opposite one another in the inner fluid duct 5a′ and with regard to structure and mode of operation correspond to those of the thermoelectric generator 1 according to FIG. 1. The corresponding explanations according to FIG. 1 therefore apply mutatis mutandis.

1. A thermoelectric generator (1),
with a housing (2), which extends along a centre longitudinal axis (M) and delimits a housing interior (3),
with a supporting structure (4) provided in the housing interior (3) and extending along the centre longitudinal axis (M), which supporting structure divides the housing interior (3) into a radially outer fluid duct (5a) for flowing through by a first fluid (F₁) and a radially inner fluid duct (5b), fluidically separated therefrom, for flowing through by a second fluid (F₂),
wherein the supporting structure (4) in a cross-section perpendicularly to the centre longitudinal axis (M) has the geometry of a polygon with at least four corners (7), so that a supporting wall (6) of the supporting structure (4) is formed respectively between two adjacent corners (8) in cross-section,
wherein on each supporting wall (6) respectively at least one thermoelectric module (8) is arranged, which is able to be thermally connected with the two fluids (F₁, F₂.)

2. The thermoelectric generator (1) according to claim 1,
characterized in that
the thermoelectric generator (1) comprises an additional inner housing (11), which in cross-section perpendicularly to the centre longitudinal axis (M) is arranged in the housing interior (3) radially within the supporting structure (4) and separates the radially inner fluid duct (5b) into a radially outer duct section (12) for flowing through by the second fluid (F₁) and a radially inner duct section (13), fluidically separated therefrom, which serves as a bypass duct (14) for the first and/or second fluid (F₁, F₂).

3. The thermoelectric generator (1) according to claim 1 or 2,
characterized in that
in each supporting wall (6) for each thermoelectric module (8) arranged on it, an aperture (9) is respectively provided, in which the thermoelectric module (8) is at least partially received, wherein the thermoelectric module (8) closes the aperture (9).

4. The thermoelectric generator (1) according to one of the preceding claims,
characterized in that
the thermoelectric modules (8) are arranged in the apertures (9) such that they terminate, in particular by means of a cover plate (22), respectively flush with a radially outer exterior side (10) of the supporting wall (6) and project radially inwards into the radially inner fluid duct (5b).

5. The thermoelectric generator (1) according to one of the preceding claims,
characterized in that
the housing (2) and/or the additional inner housing (11) have respectively a substantially cylindrical geometry.

6. The thermoelectric generator (1) according to one of claims 2 to 5,
characterized in that
a thermal insulation element (15) of a thermally insulating material is provided respectively between two thermoelectric modules (8) adjacent in cross-section.

7. The thermoelectric generator (1) according to claim 6,
characterized in that
the thermal insulation element (15) rests radially internally on the additional inner housing (11) and radially externally on the supporting structure (4).

8. The thermoelectric generator (1) according to one of the preceding claims,
characterized in that
on a radially inner internal side (16) of the thermoelectric module (8) a rib-like structure (17) is arranged, which projects into the radially inner fluid duct (5b).

9. The thermoelectric generator (1) according to claim 8,
characterized in that
the rib-like structure (17) has a wave-shaped geometry in cross-section,
the rib-like structure (17) is fastened radially externally in a materially connected manner, in particular by means of a soldered connection, to the radially inner internal side (16) of the thermoelectric module (8) and rests in particular radially internally on the additional inner housing (11).

10. The thermoelectric generator (1) according to one of the preceding claims,
characterized in that
the supporting structure (4) rests on the housing (2) by means of a plurality of holding webs (20), extending respectively in radial direction, which are arranged along a circumferential direction (U) of the housing (2) at a distance from one another in the radially outer fluid duct (5a).

11. A thermoelectric generator (1′),
with an outer housing (3′) delimiting a housing interior (2′),
with an inner housing (4′), arranged in the housing interior (2′), which housing divides the housing interior (2′) into an outer fluid duct (50 for flowing through by a first fluid (F₁) and an inner fluid duct (5a′), fluidically separated therefrom, for flowing through by a second fluid (F₂),
wherein the inner housing (4′) comprises a first and a second housing wall (6a′, 6b′), which lie opposite one another and in which respectively at least one aperture (7a′, 71b′) is provided,
wherein a thermoelectric module (8a′, 8b′) is inserted into each aperture (7a′, 7b′), so that it closes the aperture (7a′, 7b′).

12. The thermoelectric generator (1′) according to claim 11,
characterized in that
the thermoelectric module (8a′, 8b′) is inserted into the respective aperture (7a′, 7b′) such that, in particular by means of a cover plate (12a′, 12b′), it terminates flush with an exterior side of the inner housing (4′), facing the outer housing (3′), and projects inwards into the inner fluid duct (5a′), so that the two thermoelectric modules (8a′, 8b′) lie opposite one another in the inner fluid duct (5a′).

13. The thermoelectric generator (1′) according to claim 11 or 12,
characterized in that
the inner and/or the outer housing (3′, 4′) are constructed as a flat tube, which extend respectively along a main flow direction (H′) of the fluid (F₁, F₂) flowing through the two fluid ducts (5a′, 5b′).

14. The thermoelectric generator (1′) according to one of claims 11 to 13,
characterized in that
the inner housing (4′) comprises a third and a fourth housing wall (6e, 6d), which in a cross-section perpendicularly to the main flow direction (H′) complete the first and second housing wall (6a′, 6b′) to the inner housing (4′),
in cross-section perpendicularly to the main flow direction (H′) on an inner side (9′) of the third housing wall (6c′) a first thermally insulating insulation element (11a′) is provided, and on an inner side (10′) of the fourth housing wall (6d) a second thermally insulating insulation element (11b′) is provided.

15. The thermoelectric generator (1′) according to one of claims 11 to 14, characterized in that
a first intermediate space (13′), in cross-section perpendicularly to the main flow direction (H), partially delimited by the two thermoelectric modules (8a′, 8b′) and the third housing wall (6c′), is filled by the first thermally insulating insulation element (11a′),
a second intermediate space (14′), in cross-section perpendicularly to the main flow direction (H′), partially delimited by the two thermoelectric modules (8a′, 8b′) and the fourth housing wall (6d), is filled by the second thermally insulating insulation element (11b′).

16. The thermoelectric generator (1′) according to claim 15,
characterized in that
the two thermally insulating insulation elements (11a′, 11b′) are part of a thermally insulating insulation device (15′), which in a longitudinal section of the inner housing (4′) along the main flow direction (H′) has a U-shaped geometry with a base section (16′) and two legs (17a′, 17b′) projecting laterally from the base section (16′),
the first thermally insulating insulation element (11a′) forms the first leg (17a′) and the second thermally insulating insulation element (11b′) forms a second leg (17b′) of the thermal insulation device (15′).

17. The thermoelectric generator (1′) according to claim 16,
characterized in that
in the base section (16′) an aperture (18′) is provided for flowing through by the second fluid (F₂).

18. The thermoelectric generator (1′) according to claim 16 or 17,
characterized in that
the thermally insulating insulation device (15′) is constructed as a structural part, in which the two legs (17a′, 17b′) are formed integrally on the base section (16′).
